(19) United States
(12) Patent Application Publication
(10) Pub. No.: US 2008/0277746 A1
(43) Pub. Date: Nov. 13, 2008

(54) Nanowire sensor with self-aligned electrode support

(75) Inventors: Sheng Teng Hsu, Camas, WA (US); Fengyan Zhang, Vancouver, WA (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(73) Assignee: Sharp Laboratories of America, Inc.

(21) Appl. No.: 11/651,234

(22) Filed: Jan. 9, 2007

Related U.S. Application Data
(63) Continuation-in-part of application No. 11/264,113, filed on Nov. 1, 2005.
Application No. 11/264,113 is a continuation-in-part of application No. 10/971,330, filed on Oct. 21, 2004, now Pat. No. 7,255,745.

(51) Int. Cl. H01L 29/41; H01L 21/20; C30B 25/00

(52) U.S. Cl. 257/414; 438/507; 117/87; 257/E21.09; 257/E29.112; 977/762

(57) ABSTRACT

A nanowire sensor with a self-aligned top electrode support insulator, and associated fabrication process are provided. The method begins with a doped silicon-containing substrate. A growth-promotion metal is deposited overlying the substrate. A silicon nitride electrode support is formed overlying the growth-promotion metal. Nanowires are grown from exposed regions of the growth-promotion metal and an insulator is deposited over the nanowires. A top insulator layer is removed to expose tips of the nanowires, and a top electrode metal is deposited overlying the nanowire tips and silicon nitride electrode support. Next, a stack etch is selectively performed, etching down to the level of the growth-promotion metal. A top electrode island is left that is centered on the silicon nitride electrode support and connected to the growth-promotion metal via the nanowires. Then, the sensor is dipped in a buffered hydrofluoric (BHF) solution, to remove any remaining insulator and to expose the nanowires.

### RELATED APPLICATIONS

This application is a Continuation-In-Part, claiming priority under 35 U.S.C. 120 of a pending patent application entitled, AMBIENT ENVIRONMENT NANOWIRE SENSOR, invented by Zhang et al., Ser. No. 11/264,113, filed on Nov. 1, 2005, which is a Continuation-In-Part of a pending patent application entitled, IRIDIUM OXIDE NANOWIRES AND METHOD FOR FORMING SAME, invented by Zhang et al., Ser. No. 10/971,330, filed Oct. 21, 2004, both of which are incorporated herein by reference.

### BACKGROUND OF THE INVENTION

1. Field of the Invention

This invention generally relates to integrated circuit (IC) fabrication and, more particularly, to a nanowire sensor with a self-aligned top electrode and a method for fabricating the same.

2. Description of the Related Art

Recently, the fabrication of nanowires has been explored, due to its potential importance as a building block in nano, microelectromechanical (MEM), and nanoelectromechanical NEM device applications. For example, researchers associated with Charles Lieber of Harvard University have reported the synthesis of a variety of semiconductor nanowires made from materials such as silicon (Si), Si-germanium (SiGe), InP, and GaN, for use in building nano-computing system. Other groups have also reported using templates structures to grow metallic nanowires made of materials such as Ni, NiSi, Au, and Pt. Metallic nanowires can be used as interconnections and the sharp tips of the nanowire make them effective for field emission purpose. For example, ZnO nanowires are potentially useful as a light emission element.

However, few processes have been reported that are able to form metallic nanowires without the use of porous material forms or templates. The templates add a considerable degree of complexity to the process. Thus, a more practical and commercially feasible means of forming metallic nanowires publications is desirable. It would be especially useful if iridium oxide (IrO₂) nanowire could be grown using a metalorganic chemical vapor deposition (MOCVD) methods without a template. IrO₂ is a conductive metal oxide that is already widely used in DRAM and FeRAM applications. IrO₂ can be used as a conductive electrode, as it has stable electrical and chemical properties, even at high temperature O₂ ambient conditions. IrO₂ can also be used as pH sensor material. Ir thin film can be deposited using PVD easily with excellent polycrystalline structure and strong (111) orientation. IrO₂ can be formed afterwards, by oxidizing the Ir film, or it can be formed directly using reactive sputtering method at higher temperatures in oxygen ambient. CVD methods have recently been developed to grow Ir and IrO₂ thin films. It is relatively easy to maintain good composition control in CVD processes, and the method is know to provide good step coverage.

Reui-San Chen et al. have published a paper that discusses the MOCVD growth of IrO₂ nanorods using (methylcyclopentadienyl) (1,5-cyclooctadiene) iridium (I) as a precursor. They have also explored the potential of using IrO₂ nanorods for field emission applications. The nanorods they grew were a few microns long and around 100 nanometers (nm) in diameter. However, successfully repeated experiments obtaining similar vertically aligned IrO₂ nanorods show that, although these structures exhibit sharp tips, the crystal structure is amorphous or polycrystalline. The crystalline structure is a result of defects, or a high dislocation density, resulting from the fact that there is insufficient diffusion to overcome the effects of shadowing during growth, which acts to provide more precursors to the nanorod tips than to the nanorod stem, or rod bottom sections.

Due to more recent successes in growing nanowires from various materials such as IrO₂, researchers have explored the fabrication of electrical devices made using nanowires. However, the fragility of the nanowires makes such devices difficult to fabricate.

It would be advantageous if low-cost sensor devices could be fabricated, taking advantage of the electrical characteristics of nanowires, having both a low leakage current and well supported top electrode.

### SUMMARY OF THE INVENTION

The present invention describes a sensor with a self-aligned top electrode support structure. To address the issue of leakage current, the sensor's nanowires are completely free from the top electrode support structure and any surrounding insulator material. To address the issue of mechanical strength, the top electrode support is not sensitive to the etching processes used to expose the nanowires.

Accordingly, a method is provided for forming a nanowire sensor with a self-aligned top electrode support insulator. The method begins with a doped silicon-containing substrate. A growth-promotion metal, such as Ti, Ni, or Au, is deposited overlying the doped silicon-containing substrate. An electrode support (e.g., silicon nitride) is formed overlying the growth-promotion metal. Nanowires are grown from exposed regions of the growth-promotion metal. To provide temporary support for the top electrode metal, an insulator such as silicon dioxide is deposited over the nanowires. A top insulator layer is removed to expose tips of the nanowires, and a top electrode metal is deposited overlying the nanowire tips and the silicon nitride electrode support. Next, a stack etch is selectively performed, etching down to the level of the growth-promotion metal. After etching, a top electrode island is left that is centered on the silicon nitride electrode support, and connected to the growth-promotion metal via the nanowires. Then, the sensor is dipped in a buffered hydrofluoric (BHF) solution, to remove any remaining temporary support insulator and to expose the nanowires. The silicon nitride electrode supports are not etched by the BHF.

Besides IrO₂, the nanowires may be a material such as TiO₂, InO, ZnO, SnO₂, Sb₂O₃, In₂O₃, carbon, Pd, Pt, Au, Mo, Si, Ge, SiGe, CdSe, AlN, ZnS, InP, InAs, It, In, or Ti. The temporary support insulator may be spin-on glass (SOG), such as silicates, phosphosilicates, or siloxanes. The insulator may also be a low-k spin-on dielectric, such as nanoglass, MSQ (CH3SiO1.5), methyl silsequioxane, or HSQ hydrogen silsequioxane (methyl Isobutyl Ketone), or silk.

Additional details of the above-described method and a nanowire sensor having a top electrode supported by a self-aligned insulator are described below.

### BRIEF DESCRIPTION OF THE DRAWINGS

FIG. 1 is a partial cross-sectional view of a sensor with nanowires embedded in the top electrode support insulator.

FIG. 2 is a partial cross-sectional view of the sensor of FIG. 1, with an intrinsic region of substrate underlying the top electrode support insulator.

FIG. 3 is a partial cross-sectional view of a nanowire sensor having a top electrode supported by a self-aligned insulator.

FIGS. 4-7 depict steps in the fabrication of the completed sensor shown in FIG. 3.

FIG. 8 is a flowchart illustrating a method for forming a nanowire sensor with a self-aligned top electrode support insulator.

### DETAILED DESCRIPTION

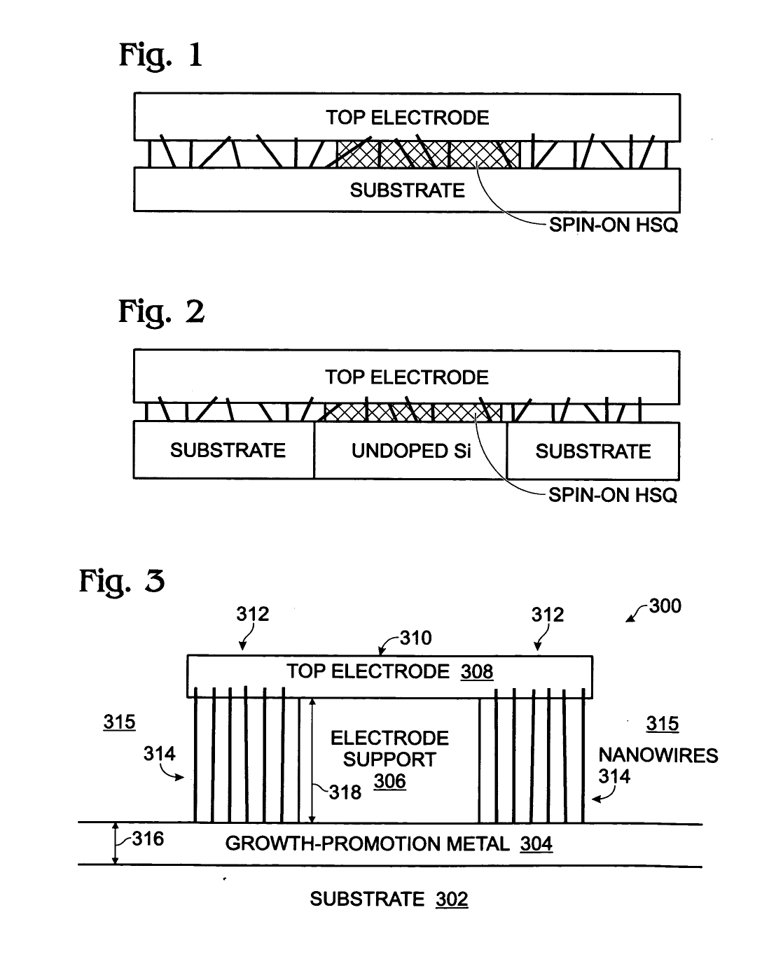

FIG. 1 is a partial cross-sectional view of a sensor with nanowires embedded in the top electrode support insulator. Although not explicitly shown in this figure, IrO₂ nanowires have been successfully grown on a Si substrate using a thin layer of Ti for growth promotion. Nanowires can also be formed on a heavily doped silicon wafer surface with a thin layer of metal particles such as Ti. After patterning the Ti layer, the selective growth of the IrO₂ nanowires can be realized. Ta, Au, Ni, Co, and similar metals can also act as the growth-promotion metal. After the deposition and definition of the top electrode, an etch is performed to remove the nanowires and HSQ from the portion of wafers that is not covered by the top electrode. Then, a BHF etch is performed to remove the HSQ under the top electrode, which exposes IrO₂ nanowires under the top electrode. The HSQ under the center portion of the device remains in place to support the top electrode.

Besides the nanowires exposed by the BHF etch, there remain nanowires embedded in the HSQ support region. The low resistance of the nanowires in the HSQ region creates a leakage current. As a result, the sensitivity of the device is not optimal.

FIG. 2 is a partial cross-sectional view of the sensor of FIG. 1, with an intrinsic region of substrate underlying the top electrode support insulator. The intrinsic substrate makes the center portion of the bottom substrate either non-conductive or poorly conductive. Therefore, nanowires embedded in the HSQ support structure do not contribute much to the device leakage current. However, if the HSQ is (mis)aligned over a highly conductivity (doped) region of silicon, or over a region of growth-promotion metal, the embedded nanowires in the overlying HSQ support structure act as a current leakage path. Again, the sensitivity may be less than optimal.

The current leakage issue can be addressed by etching sufficiently to ensure that all HSQ is removed overlying the highly conductive silicon substrate and growth-promotion metal regions. However, if too much HSQ is removed, support for top electrode may be inadequate, and the device may have poor reliability.

FIG. 3 is a partial cross-sectional view of a nanowire sensor having a top electrode supported by a self-aligned insulator. The sensor 300 comprises a doped silicon-containing substrate 302, which may be either n or p doped. A growth-promotion metal 304 overlies the doped silicon-containing substrate 302. In some aspects not shown, nanowires are grown without the use of a growth-promotion metal. A silicon nitride electrode support 306 is formed overlying the growth-promotion metal 304. A top metal electrode 308 has a center region 310 and edge regions 312. The top metal electrode 308 is formed overlying the silicon nitride electrode support 306. A plurality of exposed nanowires 314 are interposed between the growth-promotion metal 304 and the top electrode edge regions 312.

Nanowires 314 are grown from the substrate 302 with the aid of the growth-promotion metal 304. It should be noted that “grown” nanowires can be distinguished from nanostructures that are grown on one substrate, “harvested”, and then dispersed onto a different substrate. For example, harvested nanowires can be spun-on in a solvent, and the solvent evaporated.

Unlike the sensors of FIGS. 1 and 2, the silicon nitride electrode support 306 is devoid of nanowires 314. Alternately stated, the nanowires 314 are exposed to an ambient environment 315. Although only a single sensor 300 is shown, it should be understood that the sensor may be part of an array of sensors, all be connected to the same doped silicon-containing substrate 302, which acts as a bottom electrode. The doped silicon-containing substrate may be a material such as a silicon-on-insulator (SOI), silicon (Si), polycrystalline Si, amorphous Si, single-crystal Si, or silicon-germanium (SiGe).

The growth-promotion metal 304 may be a material such as Ti, Ni, Au, Ta, Co, Ir, or Pt. However, other metals with similar characteristics are known in the art that may also be used. Typically, the growth-promotion metal 304 has a thickness 316 in a range of about 0.1 to 10 nanometers (nm). Typically, the silicon nitride electrode support 306 has a thickness 318 is a range of about 0.5 to 2 microns. It is the support thickness 318 that is primarily responsible for the length of the nanowires 314. Therefore, the thickness 318 may be varied from the above-mentioned limits to support different nanowire lengths. The top metal electrode 308 may be a metal such as Al, TiN, Pt, Ir, or Au. However, many other conductive materials are known in the art that may also be used.

The present invention sensor design may be implemented with nanowires made from a number of different materials. The nanowires 314 may be IrO₂, TiO₂, InO, ZnO, SnO₂, Sb2O₃, In2O₃, carbon, Pd, Pt, Au, Mo, Si, Ge, SiGe, CdSe, AlN, ZnS, InP, InAs, Ir, In, or Ti. Again, other unnamed materials are known in the art that may be used. Further, in addition to simple one-material nanowires, the nanowires 314 may be a core and shell structure made from a combination of two of the above-mentioned materials, or nanoparticle-coated nanowires. For example, Pd particles coating TiO₂ nanowires may be employed. The nanowires 314 may have a segmented axis structure, where each segment is made from one of the above-mentioned materials. Further, the nanowires may have a multiple stacked or multi-layer structure, where each layer in the stack is made from one of the above-mentioned materials.

The nanowires may have a circular cross-section. In other aspects the nanowires may have a square, triangular, or oval shape. Further, is some aspects not shown, there may be a cavity or hollow region in the center of the core. Alternately, a nanowire may be referred to as a nanorod, nanostructure, or nanotube.

### Functional Description

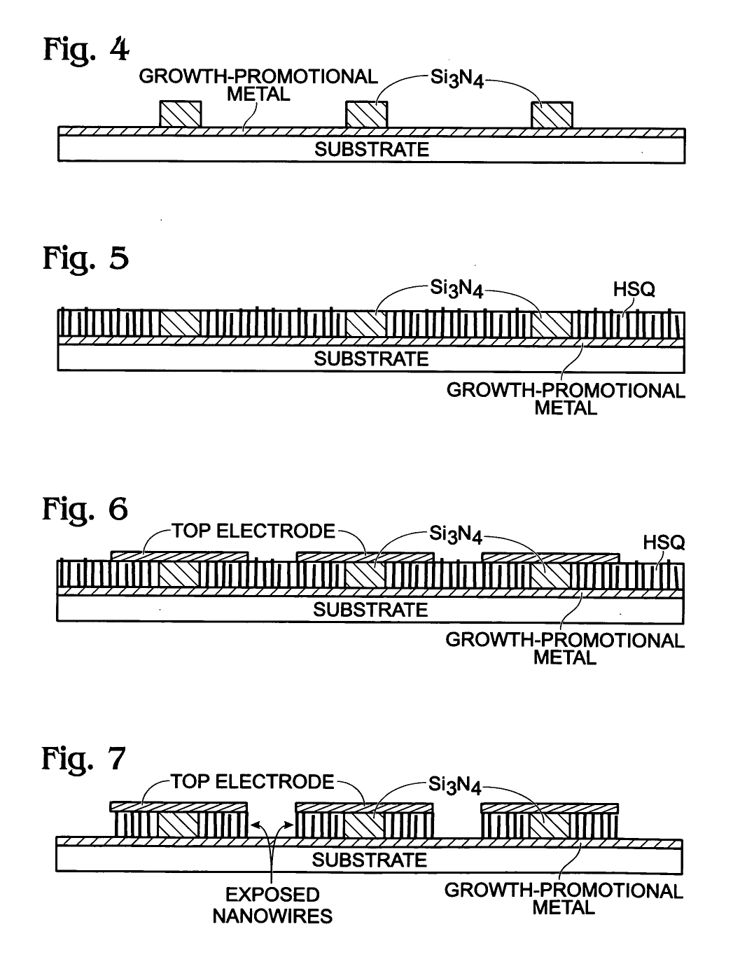

FIGS. 4-7 depict steps in the fabrication of the completed sensor shown in FIG. 3. The fabrication process is started using a substrate of Si, poly-Si, or polysilicon-on-oxide, to name a few examples. The surface of the substrate is heavily doped to enhance the bottom electrode conductivity. A thin layer of nanowires growth promoting layer metal, such as Ti, is deposited on the surface of the substrate. The thickness of this metal layer is in the range of 1.0 to 10 nm. Ni, Au, Ta, Co, Ir, Pt may also be used as the nanowire growth-promotion layer. Annealing is performed in an O₂, N₂, Ar, vacuum, or forming gas at 300-1000° C., to activate the promotion layer and enhance the nanowires growth.

In FIG. 4 a layer of Si₃N₄ is deposited onto the nanowires growth promoting metal. The thickness of the nitride layer is in the order of 0.5 microns (μm) to 2 μm. Typically, the nitride layer thickness is slightly thinner than the desired length of the nanowires. Photoresist is used as mask to etch the silicon nitride. The remaining silicon nitride is used as the top electrode support insulator. Although silicon nitride is used as an example, other insulators are known in the art that are resistive to BHF.

Then, the wafer is transferred to a growth chamber fro nanowire growth. If IrO₂ nanowires are grown, (Methylcyclopentadienyl)(1,5-cyclooctadiene)iridium(I) may be used as precursor. Both the precursor and the transport line are maintained at a constant temperature of 60-100° C. High purity oxygen at a flow rate of 50-500 standard cubic centimeters (sccm) is used as the reaction gas. Ar gas is introduced at a flow rate of 50-500 sccm as carrier gas through the ampoule of the Ir precursor. The base pressure for metalorganic chemical valor deposition (MOCVD) process is from 1×10⁻⁸ to 1×10⁻³ torr. Then, the chamber pressure is increased to 1-500 torr. Preferably, a pressure of 10-100 torr is maintained using an O₂ bypass line, before introducing the precursor into the growth chamber. The growth temperature in the chamber is from 200-500° C., with 300-400°C. being preferred. The pressure of the chamber is held at 1-500 torr, and preferably at 10-100 torr during growth.

After the nanowires are grown, an insulator is deposited. The insulator may be a spin on glass (SOG), such as silicates, phosphosilicate, and siloxanes, or a low-k spin-on dielectric, such as nanoglass, MSQ (CH3SiO1.5), methyl silsesquioxane, and HSQ hydrogen silsesquioxane ( methyl Isobutyl Ketone). The insulator can also be silk. The insulator is applied to coat and cover the IrO₂ nanowires, and to create a flat surface. Multiple layers of the SOG can be applied, if needed, to cover the nanowires. For an HSQ solution, the spin speed is from 100-10000 RPM. A baking is performed after each spin-on layer, at a temperature in the range of 100-400° C. After finishing the HSQ deposition, a further annealing of the structure is performed in a temperature range of 400-1000° C. to obtain stoichiometric SiO₂ films. Then, a brief dip in the HF solution is performed to expose the tips of the nanowires. Optionally, a CMP is performed to flatten the surface of the insulator. If a CMP process is used, the Si3N₄ can act as the CMP stop layer, see FIG. 5.

After exposing the tips of the nanowires, a top metal layer, such as Al, TiN, Pt, Ir, Au, or the like, can be deposited on top of the exposed IrO₂ nanowires tips. Photoresist is deposited on top of the metal layer and patterned. The top metal layer is patterned next using a dry etching process, see FIG. 6.

The oxide layer (insulator) and exposed IrO₂ nanowires tips are etched away afterwards, with the photoresist either being left or first striped away, depending on the etching process being used. After the stack etching of the top metal/SOG+nanowires, the wafer is dipped in a BHF solution to remove all SOG. The BHF solution does not etch Si3N₄. Therefore, the Si3N₄ remains on place to support the top electrode, while all the IrO₂ nanowires are exposed. The leakage current through the top electrode support layer is negligibly small. Thus, the resultant device has a high sensitivity. Since the BHF solution does not etch Si3N₄, the etch step is self limited. A self-aligned structure is achieved, see FIG. 7. Although BHF has explicitly been mentioned, other etchants are known in the art that are selective to different types of insulators. These unnamed insulator-selective etchants may also be used to enable the present invention.

A brief annealing of the structure may be performed either before, or after the BHF etching, to strengthening the nanowires connection with the top electrode and bottom substrate. The annealing can be performed in N₂, Ar, Forming gas, vacuum, or O₂, in the temperature range at 200-1000° C., for about 10-3600 sec.

Although IrO₂ nanowires have explicitly been described, the above-described general process can also be applied to other nanowire sensors applications, such as metal oxide nanowires TiO₂, InO, ZnO, SnO2, Sb2O3, and In2O3, carbon nanotubes, metal nanowires, such as Pd, Pt Au, Mo, and semiconductor nanowires such as Si, Ge, SiGe, CdSe, AlN, ZnS, GaN, InP, and InAs. The process also has application to core-shell nanowire structures, with another sensing material uniformly coating the nanowires, such as TiO₂ coated IrO₂ nanowires. Nanoparticle-coated nanowires, such as Pd particles coated TiO₂ nanowires, or multiple stacked nanowires arrays may also be formed.

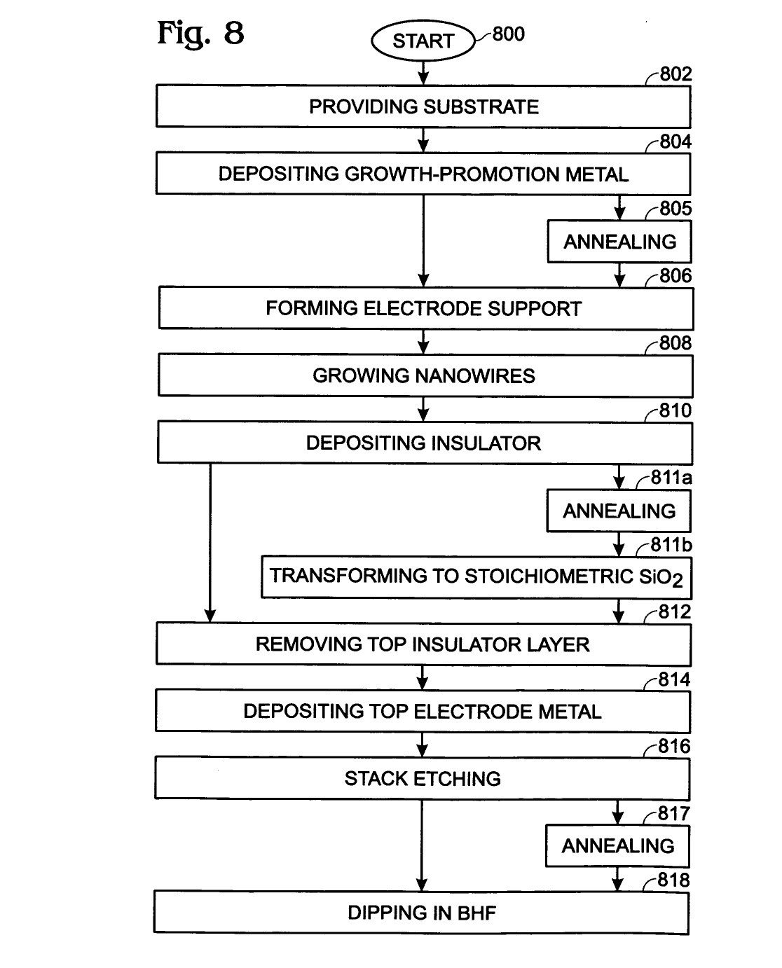

FIG. 8 is a flowchart illustrating a method for forming a nanowire sensor with a self-aligned top electrode support insulator. Although the method is depicted as a sequence of numbered steps for clarity, no order need necessarily be inferred from the numbering. It should be understood that some of these steps may be skipped, performed in parallel, or performed without the requirement of maintaining a strict order of sequence. The method starts at Step 800.

Step 802 provides a doped silicon-containing substrate. The doped silicon-containing substrate may be a material such as SOI, Si, polycrystalline Si, or SiGe, to name a few examples. Step 804 deposits a growth-promotion metal overlying the doped silicon-containing substrate. The growth-promotion metal may be Ti, Ni, Au, Ta, Co, Ir, or Pt. The growth-promotion metal may have a thickness in the range of about 0.1 to 10 nm. Step 806 forms a silicon nitride electrode support overlying the growth-promotion metal. More specifically, Step 806 includes the substeps of depositing a silicon nitride layer having a thickness in a range of about 0.5 to 2 microns, and selectively etching the silicon nitride layer.

Step 808 grows nanowires from exposed regions of the growth-promotion metal. The nanowire may be a material such as IrO₂, TiO₂, InO, ZnO, SnO₂, Sb₂O₃, In2O₃, carbon, Pd, Pt, Au, Mo, Si, Ge, SiGe, CdSe, AlN, ZnS, InP, InAs, It, In, or Ti. In addition to a uniform single-material construction, the nanowire may be a core and shell structure made from a combination of two of the above-mentioned materials, a nanoparticle-coated nanowire, a segmented axis structure where each segment is made from one of the above-mentioned materials, or a multiple stacked structure, where each layer in the stack is made from one of the above-mentioned materials. Step 810 deposits an insulator overlying the nanowires. The insulator may be a SOG, such as silicates, phosphosilicates, and siloxanes, a low-k spin-on dielectric, such as nanoglass, MSQ (CH3SiO1.5), methyl silsequioxane, and HSQ hydrogen silsequioxane (methyl Isobutyl Ketone), or silk.

Step 812 removes a top insulator layer, exposing tips of the nanowires. For example a hydrofluoric (HF) acid dip may be used, a chemical mechanical polish (CMP), or a CMP followed by an HF dip. Step 814 deposits a top electrode metal overlying the nanowire tips and silicon nitride electrode support. The top electrode metal may be Al, TiN, Pt, Ir, or Au for example. Step 816 selectively stack etches down to the level of the growth-promotion metal. Step 816 leaves a top electrode island centered on the silicon nitride electrode support, and connected to the growth-promotion metal via the nanowires. Step 818 dips the sensor in a BHF solution, removing any remaining insulator and exposing the nanowires.

In one aspect following the deposition of the growth-promotion metal, Step 805 anneals in an atmosphere such as O2, N2, Ar, a vacuum, or forming gas, at a temperature in a range of about 300 to 1000° C.

In another aspect, growing nanowires in Step 808 includes growing IrO₂ nanowires using a MOCVD process as follows:

introducing a (Methylcyclopentadienyl)(1,5-cyclooctadiene)Iridium(I) precursor at a temperature in the range of about 60 to 100° C.;

introducing high purity oxygen at a flow rate in the range of about 50 to 500 sccm;

introducing Ar at a flow rate in the range of about 50 to 500 sccm, as a carrier gas for the Ir precursor;

establishing a base pressure in the range of about 1×10⁻⁸ to 1×10⁻³ torr, and using an O₂ bypass line, creating a subsequent pressure in the range of about 1 to 500 torr before the introduction of the Ir precursor; and,

maintaining a substrate temperature in the range of about 200 to 500° C.

In another aspect, depositing the insulator in Step 810 includes depositing HSQ as follows:

depositing a plurality of HSQ layers, using a spin rate in the range of about 100 to 10,000 revolution per minute (RPM); and, after each HSQ layer deposition, baking at a temperature in the range of about 100 to 400° C.

Following the deposition of a HSQ insulator, Step 811a optionally anneals at a temperature in the range of about 400 to 1000° C. In response to the annealing, Step 811b transforms the insulator into a stoichiometric composition Si oxide layer.

In another aspect following the stack etching in Step 816, Step 817 anneals at a temperature in a range of about 200 to 1000° C. for a duration in the range of about 10 to 3600 seconds, in an atmosphere such as O₂, N₂, Ar, a vacuum, or a forming gas. Step 817 may be performed after Step 816 or after Step 818.

A nanowire senor with a self-aligned top electrode support structure, and an associated fabrication method have been provided. A few examples of process specifics and materials have used to illustrate the invention. However, the invention is not limited to just these examples. Other variations and embodiments of the invention will occur to those skilled in the art.

We claim:

1. A method for forming a nanowire sensor with a self-aligned top electrode support insulator, the method comprising:
providing a doped silicon-containing substrate;
depositing a growth-promotion metal overlying the doped silicon-containing substrate;
forming a silicon nitride electrode support overlying the growth-promotion metal;
growing nanowires from exposed regions of the growth-promotion metal;
depositing an insulator overlying the nanowires;
removing a top insulator layer, exposing tips of the nanowires;
depositing a top electrode metal overlying the nanowire tips and silicon nitride electrode support;
selectively stack etching down to the level of the growth-promotion metal, leaving a top electrode island centered on the silicon nitride electrode support, and connected to the growth-promotion metal via the nanowires; and,
dipping the sensor in a buffered hydrofluoric (BHF) solution, removing any remaining insulator and exposing the nanowires.

2. The method of claim 1 wherein depositing the growth-promotion metal includes depositing a material selected from a group consisting of Ti, Ni, Au, Ta, Co, Ir, and Pt.

3. The method of claim 2 wherein depositing the growth-promotion metal includes forming the growth-promotion metal to a thickness in a range of about 0.1 to 10 nanometers (nm).

4. The method of claim 2 further comprising:
following the deposition of the growth-promotion metal, annealing in an atmosphere selected from a group consisting of O2, N2, Ar, a vacuum, and forming gas, at a temperature in a range of about 300 to 1000° C.

5. The method of claim 1 wherein growing nanowires includes growing nanowires from a material selected from a group consisting of IrO₂, TiO₂, InO, ZnO, SnO₂, Sb₂O₃, In₂O₃, carbon, Pd, Pt, Au, Mo, Si, Ge, SiGe, CdSe, AlN, ZnS, InP, InAs, It, In, Ti, a core and shell structure made from a combination of two of the above-mentioned materials, a nanoparticle-coated nanowire, a segmented axis structure where each segment is made from one of the above-mentioned materials, and a multiple stacked structure, where each layer in the stack is made from one of the above-mentioned materials; and,

6. The method of claim 1 wherein growing nanowires includes growing IrO₂ nanowires using a metalorganic chemical vapor deposition (MOCVD) process as follows:
introducing a (Methylcyclopentadienyl)(1,5-cyclooctadiene)Iridium(I) precursor at a temperature in the range of about 60 to 100° C.;
introducing high purity oxygen at a flow rate in the range of about 50 to 500 standard cubic centimeters (sccm);
introducing Ax at a flow rate in the range of about 50 to 500 sccm, as a carrier gas for the Ir precursor;
establishing a base pressure in the range of about 1×10⁻⁸ to 1×10⁻³ torr, and using an O₂ bypass line, creating a subsequent pressure in the range of about 1 to 500 torr before the introduction of the Ir precursor; and,
maintaining a substrate temperature in the range of about 200 to 500° C.

7. The method of claim 1 wherein depositing the insulator includes depositing a material selected from a group consisting of spin-on glass (SOG), including silicates, phosphosilicates, and siloxanes, and low-k spin-on dielectrics, including nanoglass, MSQ (CH3SiO1.5), methyl silsequioxane, and HSQ hydrogen silsequioxane (methyl Isobutyl Ketone), and silk.

8. The method of claim 1 wherein depositing the insulator includes depositing HSQ as follows:
depositing a plurality of HSQ layers, using a spin rate in the range of about 100 to 10,000 revolution per minute (RPM); and,
after each HSQ layer deposition, baking at a temperature in the range of about 100 to 400° C.

9. The method of claim 8 further comprising:
following the deposition of a HSQ insulator, annealing at a temperature in the range of about 400 to 1000° C.; and,
in response to the annealing, transforming the insulator into a stoichiometric composition Si oxide layer.

10. The method of claim 1 further comprising:
following the stack etching, annealing at a temperature in the range of about 200 to 1000° C. for a duration in the range of about 10 to 3600 seconds, in an atmosphere selected from a group consisting of O₂, N₂, Ar, a vacuum, and forming gas.

11. The method of claim 1 wherein providing the doped silicon-containing substrate includes forming a substrate from a material selected from a group consisting of silicon-on-insulator (SOI), silicon (Si), polycrystalline Si, and silicon-germanium (SiGe).

12. The method of claim 1 wherein forming the silicon nitride electrode support includes:
depositing a silicon nitride layer having a thickness in a range of about 0.5 to 2 microns; and,
selectively etching the silicon nitride layer.

13. The method of claim 1 wherein removing the top insulator layer, exposing tips of the nanowires, includes a process selected from a group consisting of hydrofluoric (HF) acid dip, a chemical mechanical polish (CMP), and a CMP followed by an HF dip.

14. The method of claim 1 wherein depositing the top electrode metal includes depositing a metal selected from a group consisting of Al, TiN, Pt, Ir, and Au.

15. A nanowire sensor having a top electrode supported by a self-aligned insulator, the sensor comprising:
a doped silicon-containing substrate;
a growth-promotion metal overlying the doped silicon-containing substrate;
a silicon nitride electrode support formed overlying the growth-promotion metal;
a top metal electrode with a center region, formed overlying the silicon nitride electrode support and edge regions;
a plurality of exposed nanowires interposed between the growth-promotion metal and the top electrode edge regions.

16. The nanowire sensor of claim 15 wherein the silicon nitride electrode support is devoid of nanowires.

17. The nanowire sensor of claim 15 wherein the nanowires are exposed to an ambient environment.

18. The nanowire sensor of claim 15 wherein the doped silicon-containing substrate is a material selected from a group consisting of silicon-on-insulator (SOI), silicon (Si), polycrystalline Si, and silicon-germanium (SiGe).

19. The nanowire sensor of claim 15 wherein the growth-promotion metal is a material selected from a group consisting of Ti, Ni, Au, Ta, Co, Ir, and Pt.

20. The nanowire sensor of claim 15 wherein the growth-promotion metal has a thickness in a range of about 0.1 to 10 nanometers (nm).

21. The nanowire sensor of claim 15 wherein the nanowires are a material selected from a group consisting of IrO₂, TiO₂, InO, ZnO, SnO₂, Sb₂O₃, In2O₃, carbon, Pd, Pt, Au, Mo, Si, Ge, SiGe, CdSe, AlN, ZnS, InP, InAs, Ir, In, Ti, a core and shell structure made from a combination of two of the above-mentioned materials, a nanoparticle-coated nanowire, a segmented axis structure where each segment is made from one of the above-mentioned materials, and a multiple stacked structure, where each layer in the stack is made from one of the above-mentioned materials.

22. The nanowire sensor of claim 15 wherein the silicon nitride electrode support has a thickness is a range of about 0.5 to 2 microns.

23. The nanowire sensor of claim 15 wherein the top metal electrode is a metal selected from a group consisting of Al, TiN, Pt, Ir, and Au.
